(19) United States
(12) Patent Application Publication
(10) Pub. No.: US 2026/0171354 A1
(43) Pub. Date: Jun. 18, 2026

(54) CHARGED PARTICLE BEAM DEVICE AND METHOD FOR CONTROLLING CHARGED PARTICLE BEAM DEVICE

(71) Applicant: HITACHI HIGH-TECH SCIENCE CORPORATION, Tokyo (JP)

(72) Inventors: Shota TORIKAWA, Tokyo (JP); Tatsuya ASAHATA, Tokyo (JP); Haruyuki ISHII, Tokyo (JP); Masahiro KIYOHARA, Tokyo (JP); Atsushi UEMOTO, Tokyo (JP)

(21) Appl. No.: 18/710,506

(22) PCT Filed: Nov. 15, 2021
(86) PCT No.: PCT/JP2021/041908

§ 371 Date: May 15, 2024

(51) Int. Cl. H01J 37/304; H01J 37/20; H01J 37/305

(52) U.S. Cl. CPC H01J 37/304; H01J 37/20; H01J 37/3053; H01J 2237/20285

(57) ABSTRACT

This charged particle beam device, which is for etching a sample, comprises: a charged particle beam-emitting optical system that emits a charged particle beam; a sample stage that holds a sample; a drive mechanism that drives the sample stage; a gas supply unit that supplies etching gas to the surface of the sample; and a computer that sets a processing region of the sample and controls the charged particle beam-emitting optical system and the drive mechanism so as to irradiate the set processing region with the charged particle beam and etch the sample. The computer sets a processing region on the sample that differs for each scan. The computer sets a different processing region for each scan on the sample.

### CROSS REFERENCE

The present application for patent is a 371 national phase filing of International Patent Application No. PCT/JP2021/041908, by TORIKAWA et al., entitled “CHARGED PARTICLE BEAM DEVICE AND METHOD FOR CONTROLLING CHARGE PARTICLE BEAM DEVICE” filed Nov. 15, 2021, assigned to the assignee hereof, and expressly incorporated by reference herein.

### TECHNICAL FIELD

The present invention relates to a charged particle beam device and a method for controlling a charged particle beam device.

### BACKGROUND ART

Some charged particle beam devices, such as focused ion beam (FIB) systems, have applications for performing deposition or gas-assisted etching processes by spraying a compound gas onto a sample. The deposition and gas-assisted etching processes are mainly carried out by decomposing compound gases adsorbed on the sample with the use of secondary electrons that are generated when the sample is irradiated with a charged particle beam. Since the secondary electron generated when the sample is irradiated with a charged particle beam is wider than the irradiated area, the charged particle beam irradiation is performed on locations that are spaced. The setting of the spacing between the irradiation locations to which the charged particle beam is emitted depends on the current density distribution of the charged particle beam.

With respect to etching processes using a charged particle beam, there are known techniques to suppress the reduction of the strength of lamella samples (see, for example, Patent Document 1). In this technology, the lamella sample preparation device is equipped with a focused ion beam (FIB)-emitting optical system, a stage, a stage drive mechanism, and a computer. The FIB optical system emits a focused ion beam. The stage holds a sample piece. The stage drive mechanism drives the stage. The computer sets a thinning processing region, which is a processing region, and a peripheral region surrounding the entire perimeter of the thinning processing region in the sample piece. The computer causes the FIB optical system to emit a focused ion beam in a direction perpendicular to the irradiated surface of the sample piece to perform etching so that the thickness of the processing region is reduced to be smaller than that of the peripheral region.

### Document of Related Art

### Patent Document

Patent Document 1: Japanese Patent Application Publication No. 2019-148550

### DISCLOSURE

### Technical Problem

Deposition and gas-assisted etching processes are performed in a manner that a compound gas adsorbed on a sample is decomposed by secondary electrons generated by irradiation of a charged particle beam. Although compound gas-deficient areas on the sample are irradiated with a beam, since there is an insufficient amount of a remaining compound gas to be decomposed, the efficiency of deposition and gas-assisted etching processes is reduced. Until that the areas on the sample are fully supplied with compound gas again, a reduction in the deposition film deposition rate or etching will occur in the deposition process in the areas, and the etching acceleration or deceleration effect of the gas-assisted etching process cannot be achieved because the gas-assisted etching process does not differ from the normal etching process and thus the time for deposition processing increases.

The present invention has been made in view of the above-described points, and it is an object to provide a charged particle beam device that can shorten the time required for deposition processing and which can efficiently obtain the effect of gas-assisted etching processing and to provide a method for controlling the charged particle beam system.

### Technical Solution

In order to solve the above problem and achieve the object, the present invention employs aspects described below.

(1) A charged particle beam device according to one aspect of the present invention is a charged particle beam device for performing a deposition process or an etching process on a sample, the device including: a charged particle beam-emitting optical system that emits a charged particle beam; a sample stage that holds a sample; a driving mechanism that drives the sample stage; a gas supply unit that supplies etching gas to the surface of the sample; and a computer that sets a processing region on the sample and controls the charged particle beam-emitting optical system and the drive mechanism so that the processing region that is set is irradiated with a charged particle beam to perform etching processing of the sample, in which the computer sets a different processing region for the sample for each scan.

(2) In the charged particle beam device described in (1) above, the computer sets a location to be irradiated with a charged particle beam as the processing region based on the diameter or current density distribution of the charged particle beam emitted by the charged particle beam-emitting optical system.

(3) In the charged particle beam device described in (1) or (2) above, the computer sets a location to be irradiated with a charged particle beam as the processing region based on acceleration voltage which the charged particle beam-emitting optical system applies to charged particles.

(4) In the charged particle beam device described in (1) or (3) above, the computer sets a location to be irradiated with a charged particle beam as the processing region based on whether charged particles in the charged particle beam emitted by the charged particle beam-emitting optical system are an electron, ion, or ionic species.

(5) In the charged particle beam device described in any one of (1) to (4) above, the computer sets a plurality of first irradiation locations spaced at predetermined intervals on the sample as the processing regions for performing deposition processing or etching processing, and sets one or more second irradiation locations between the first irradiation locations that are adjacent.

(6) In the charged particle beam device described in any one of (1) to (5) above, the computer sets a different processing region for each scan in two orthogonal directions on the sample as the processing region for the deposition processing or etching process.

(7) A method for controlling a charged particle beam device, according to one aspect of the present invention, is a method for controlling a charged particle device performing deposition processing or etching processing on a sample and including a charged particle beam-emitting optical system that emits a charged particle beam, a sample stage that holds a sample, a drive mechanism that drives the sample stage, a gas supply unit that supplies etching gas to the surface of the sample, and a computer that sets a processing region of the sample, the method including: a step in which the computer sets a different processing region for each scan for the sample; and a step in which the computer controls the charged particle beam-emitting optical system and the drive mechanism to irradiate the set processing region with the charged particle beam to perform etching processing of the sample.

### Advantageous Effects

According to the present invention, the time required for the deposition processing can be reduced and a gas-assisted etching effect can be efficiently obtained.

### DESCRIPTION OF RELATED ART

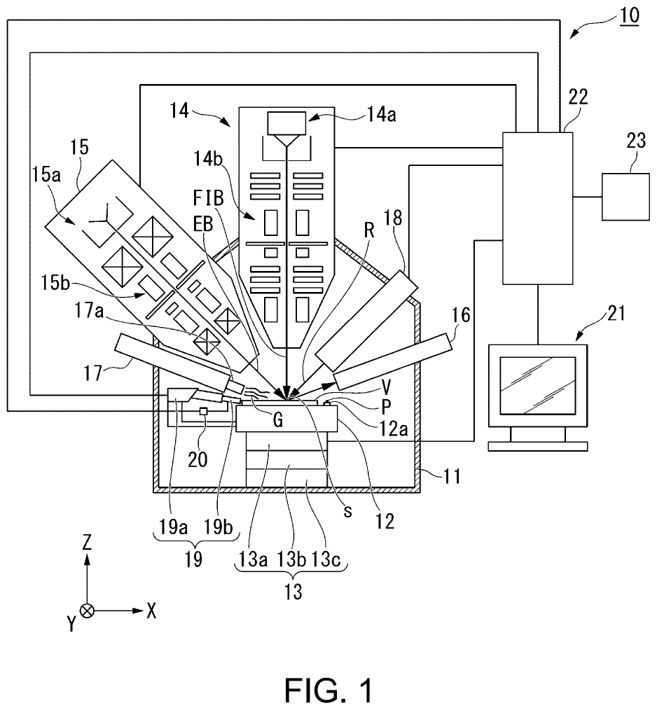

FIG. 1 is a schematic configurational diagram illustrating a charged particle beam device according to one embodiment of the present invention.

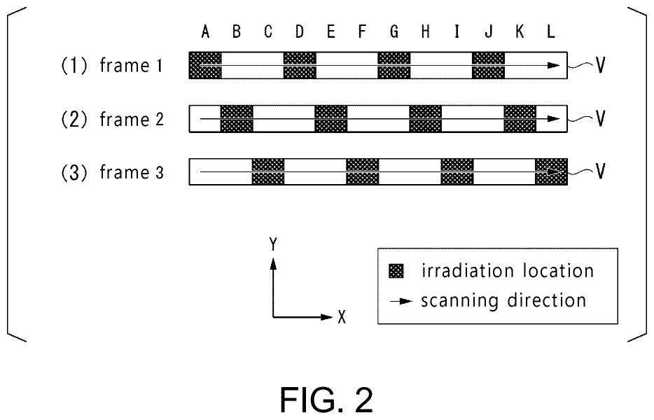

FIG. 2 is a diagram illustrating Example 1 of a location to be irradiated with a charged particle beam of the charged particle beam device according to the embodiment.

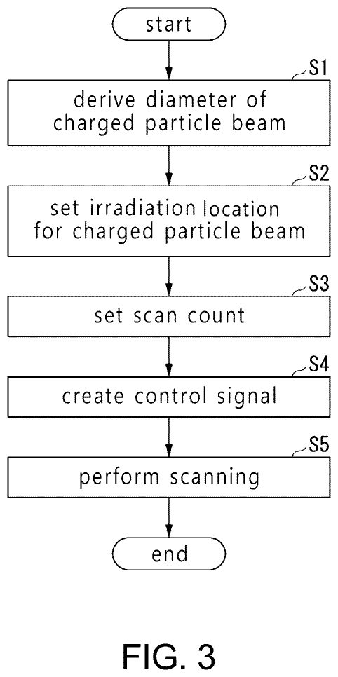

FIG. 3 is a flowchart illustrating processing procedures of the charged particle beam device according to the embodiment.

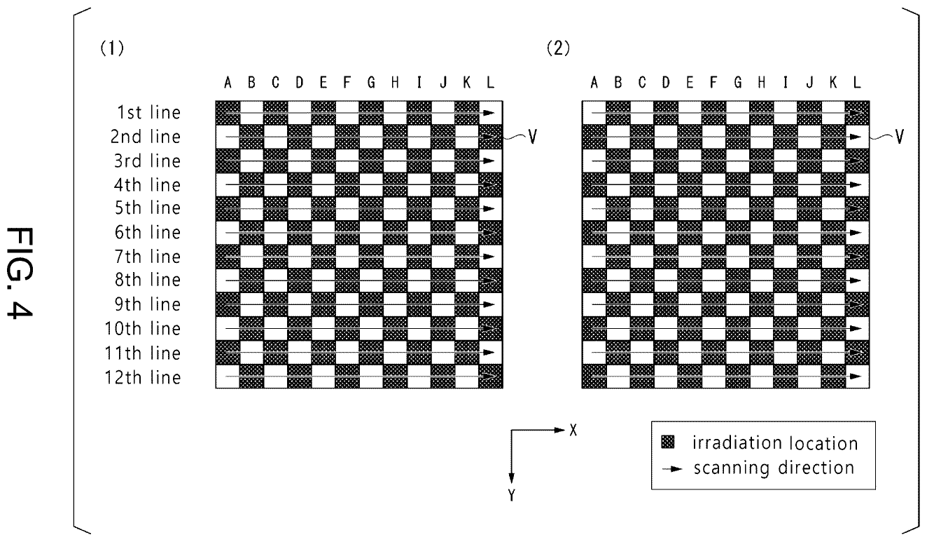

FIG. 4 is a diagram illustrating Example 2 of a location to be irradiated with a charged particle beam of the charged particle beam device according to the embodiment.

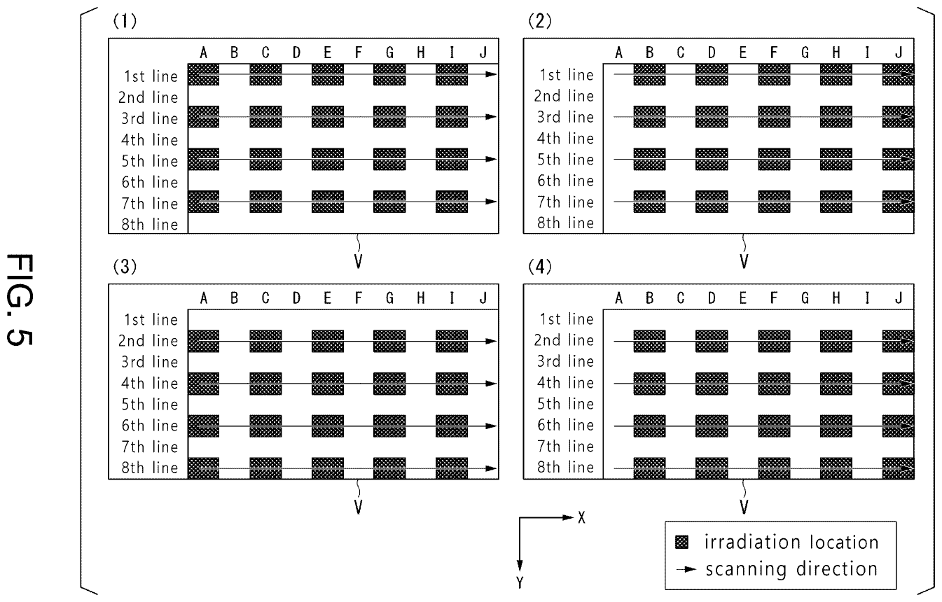

FIG. 5 is a diagram illustrating Example 3 of a location to be irradiated with a charged particle beam of the charged particle beam device according to the embodiment.

### BEST MODE

Next, a charged-particle beam device and a control method of the charged-particle beam device will be described with reference to the drawings. The embodiments described below are only for illustrative purposes, and embodiments of the present invention are not limited thereto.

Throughout the drawings used to describe the embodiments, parts having the same function are denoted by the same symbols, and a redundant description of such parts will be omitted.

FIG. 1 is a schematic configurational diagram illustrating a charged particle beam device according to one embodiment of the present invention.

The charged particle beam device 10 of the present invention performs a deposition or etching process on a sample. The charged particle beam device 10 emits a charged particle beam. The charged particle beam device 10 includes: a charged particle beam-emitting optical system that emits a charged particle beam; a sample stage for holding a sample; a driving mechanism that drives the sample stage; a gas supply unit that supplies gas for deposition or gas-assisted etching processes to the surface of the sample; and a computer that sets a processing region on the sample and controls the charged particle beam-emitting optical system and the drive mechanism to apply a charged particle beam to the processing region so that the deposition process or the etching process can be performed on the sample. The computer sets a different processing region for each scan on the sample. Specifically, as illustrated in FIG. 1, the charged particle beam device 10 includes a sample chamber 11 whose interior can be maintained in a vacuum state, a stage 12 that can fix a bulk sample V or a sample piece holder P that holds a sample piece S in the sample chamber 11, and a stage driving mechanism 13 that drives the stage 12.

The charged particle beam device 10 is equipped with a focused ion beam (FIB) irradiation optical system 14 that emits a charged particle beam such as a focused ion beam (FIB) to an irradiation target within a predetermined irradiation region (i.e., scanning range) in the sample chamber 11. The charged particle beam device 10 is equipped with an electron beam-emitting optical system 15 that emits an electron beam (EB) to an irradiation target within a predetermined irradiation region in the sample chamber 11. The charged particle beam device 10 is equipped with a detector 16 that detects secondary charged particles (such as secondary electrons and secondary ions) R generated from the irradiation target irradiated with the charged particle beam. The charged particle beam device 10 is equipped with a gaseous ion beam-emitting optical system 18 that emits a gaseous ion beam (GB) to an irradiation target in a predetermined irradiation region in the sample chamber 11.

The focused ion beam-emitting optical system 14, the electron beam-emitting optical system 15, and the gaseous ion beam-emitting optical system 18 are arranged so that the beam irradiation axes thereof intersect at substantially a single point on the stage 12. That is, when the sample chamber 11 is viewed in plane from one side, the focused ion beam-emitting optical system 14 is positioned along the vertical direction, and the electron beam-emitting optical system 15 and the gas ion beam optical system 18 are positioned along an oblique direction inclined at angle of 45° with respect to the vertical direction. With such an arrangement layout, when the sample chamber 11 is viewed in plan from one side, the beam irradiation axis of the gas ion beam (GB) orthogonally intersects the beam irradiation axis of the electron beam (EB) irradiated from the electron beam-emitting optical system 15.

The charged particle beam device 10 is equipped with a gas supply unit 17 that supplies gas to the surface of the sample S. An example of the gas supply unit 17 is specifically a nozzle 17a with an outer diameter of about 200 μm.

The charged particle beam device 10 includes a sample transfer means 19 and an absorption current detector 20. Here, the sample transfer means 19 includes a needle 10a that takes a sample piece S from a sample V fixed on the stage 12, holds the sample piece S, and transfers the sample piece S to the sample piece holder P, and the sample transfer means 19 further includes a needle driving mechanism 19 consisting of a needle driving mechanism 19b that drives the needle 19a to transfer the sample piece S. The absorption current detector 20 detects a charged particle beam inflow current (also referred to as absorption current) flowing through the needle 19a and sends an inflow current signal to the computer so that the inflow current signal can be imaged.

The charged particle beam device 10 is equipped with a display device 21 that displays image data and other data on the basis of the secondary charged particles R detected by the detector 16, a computer 22, and an input device 23.

The irradiation target of the focused ion beam-emitting optical system 14 and the irradiation target of the electron beam-emitting optical system 15 are the sample V fixed on the stage 12, the sample piece S, and the needle 19a or sample piece holder P disposed in the irradiation region.

The charged particle beam device 10 can perform imaging of the irradiated region, sputtering-assisted processing (such as drilling and trimming), etching processing, deposition film formation, etc. by scanning the surface of the irradiation target with a charged particle beam. The charged particle beam device 10 can perform a process of cutting a sample piece S from a sample V and processing the sample piece S to form a micro sample piece Q for observation with a transmission electron microscope (TEM) or an analytical sample piece using an electron beam. An example of the micro sample piece Q is a lamella sample, needle-shaped sample, etc.

The charged particle beam device 10 is capable of thinning, for example, the tip of a sample piece S transferred to the sample piece holder P until the tip of the sample has the desired thickness suitable for transmission electron microscopic observation (for example, thickness of 5 nm to 100 nm), thereby obtaining a micro sample piece Q for observation. The charged particle beam device 10 enables observation of the surface of the irradiation target by applying a charged particle beam or an electron beam to the surface of the irradiation target such as the sample piece S and the needle 19a while scanning the surface of the irradiation target.

The absorption current detector 20 is equipped with a preamplifier that amplifies the current flowing into the needle and sends the amplified current to the computer 22. The needle inflow current detected by the absorption current detector 20 and the signal synchronized with the scanning of the charged particle beam enable the display device 21 to display a needle-shaped absorption current image so that the needle shape or the needle tip position can be identified.

The sample chamber 11 can be evacuated by an air exhauster (not illustrated) until the interior of the sample chamber 11 reaches the desired vacuum state and maintain the desired vacuum state.

The stage 12 holds the sample V. The stage 12 is equipped with a holder fixing stand 12a that holds the sample piece holder P thereon. This holder fixing stand 12a may be structured to support a plurality of sample piece holders P.

The stage driving mechanism 13 is disposed in the sample chamber 11 in a state of being connected to the stage 12, and displaces the stage 12 with respect to a predetermined axis according to a control signal output from the computer 22. The stage driving mechanism 13 is equipped with a moving mechanism 13a that moves the stage 12 along each of X and Y axes that are parallel to the horizontal plane and are orthogonal to each other, and along Z axis that is orthogonal to each of the X and Y axes. The stage driving mechanism 13 includes a tilt mechanism 13b that tilts the stage 12 around the X or Y axis and a rotation mechanism 13c that rotates the stage 12 around the Z axis.

The focused ion beam-emitting optical system 14 is fixed to the sample chamber 11, with the beam emitting portion (not illustrated) thereof facing down the stage 12 in the vertical direction within the irradiation region in the sample chamber, and with the optical axis thereof being parallel to the vertical direction. This arrangement makes it possible to perpendicularly apply a charged particle beam to the irradiation target such as the sample V mounted on the stage 12, the sample piece S, or the needle 19a disposed within the irradiation region directly from above the irradiation target object.

The charged particle beam device 10 may be equipped with other ion beam-emitting optical systems instead of the focused ion beam-emitting optical system 14 described above. The ion beam-emitting optical system is not limited to the optical system that forms a charged particle beam as described above. The ion beam-emitting optical system may be, for example, a projection-type ion beam-emitting optical system that provides a stencil mask with a shaped opening in the optical system and forms a shaped beam with the shape of the opening of the stencil mask. This projection-type ion beam-emitting optical system can form a shaped beam with a shape corresponding to the processing region around the sample piece S with high precision and can reduce the processing time.

The focused ion beam-emitting optical system 14 is equipped with an ion source 14a that generates ions and an ion optical system 14b that focuses and deflects the ion extracted from the ion source 14a. The ion source 14a and the ion optical system 14b are controlled according to control signals output from the computer 22, and the irradiation location and irradiation conditions of the charged particle beam are controlled by the computer 22.

The ion source 14a is, for example, a liquid metal ion source using liquid gallium or the like, a plasma ion source, or a gas field ion source. The ion optical system 14b is equipped with, for example, a first electrostatic lens, such as a condenser lens, an electrostatic deflector, and a second electrostatic lens, such as an objective lens. When a plasma-type ion source is used as the ion source 14a, high-speed processing can be achieved with a high-current beam which makes it suitable for the extraction of large-sized sample pieces S. For example, by using argon ions as a gas field ion source, an argon ion beam can be emitted from the focused ion beam-emitting optical system 14.

The electron beam-emitting optical system 15 is fixed to the sample chamber 11, with the beam emitting portion (not illustrated) thereof facing down the stage 12 in an oblique direction inclined by a predetermined angle (for example, 60°) with respect to the perpendicular direction of the stage 12 within the irradiation region inside the sample chamber 11, and with the optical axis thereof being parallel to the oblique direction. This arrangement makes it possible to apply an electron beam to the irradiation target such as the sample V fixed to the stage 12, the sample piece S, and the needle 19a disposed within the irradiation region, from above the irradiation target object in the oblique direction.

The electron beam-emitting optical system 15 is equipped with an electron source 15a that generates electrons and an electron optical system 15b that focuses and deflects the electrons emitted from the electron source 15a. The ion source 15a and the ion optical system 15b are controlled according to control signals output from the computer 22, and the irradiation location and irradiation conditions of the electron beam are controlled by the computer 22. The electron optical system 15b is equipped with, for example, an electromagnetic lens and a deflector.

The positions of the electron beam-emitting optical system and focused ion beam-emitting optical system 14 may be switched, so that the electron beam-emitting optical system 15 may be positioned in the vertical direction and the focused ion beam-emitting optical system 14 may be positioned in the oblique direction inclined by a predetermined angle with respect to the 15 vertical direction.

The gaseous ion beam-emitting optical system 18 emits a gaseous ion beam (GB), such as an argon ion beam. The gaseous ion beam-emitting optical system 18 can ionize argon gas and emits a beam of the generated argon ions at a low acceleration voltage of about 1 kV. Such gaseous ion beams (GBs) are less focused than focused ion beams (FIBs), resulting in lower etching rates on the sample piece S or micro sample piece Q. Therefore, GBs are suitable for precision finishing processing of the sample piece S or micro sample piece Q.

The detector 16 detects the intensity (i.e., amount) of secondary charged particles R (i.e., secondary electrons or secondary ions) emitted from the irradiation target when the irradiation targets such as the sample V, sample piece S, and needle 19a are irradiated with the charged particle beam or the electron beam and outputs information on the detected amount of the secondary charged particles R. The detector 16 is disposed inside the sample chamber 11 at a location where the amount of secondary charged particles R can be detected, for example, at a location obliquely above the irradiation target such as the sample V or Sample S in the irradiation region. The detector 16 is fixed to the sample chamber 11.

The gas supply unit 17 is fixed to the sample chamber 11 and has a gas ejection unit (also referred to as a nozzle) inside the sample chamber 11, and is arranged to face the stage 12. The gas supply unit 17 can supply an etching gas to selectively promote etching of the sample V or sample piece S depending on the material of the sample V or sample piece S when the sample V or sample piece S is etched by the charged particle beam and can supply a deposition gas to form a metal or insulator deposition film on the surface of the sample V or sample piece S.

The needle driving mechanism 19b, which is a part of the sample piece transfer means 19, is disposed inside the sample chamber 11 in a state of being connected with the needle 19a, and displaces the needle 19a according to a control signal output from the computer 22. The needle driving mechanism 19b is integrated with the stage 12. For example, when the stage 12 is rotated around the tilt axis (i.e., X or Y axis) by the tilt mechanism 13b, the needle driving mechanism 19b and the stage 12 move together.

The needle driving mechanism 19b has a moving mechanism (not illustrated) that moves the needle 19a in parallel along each of the three-dimensional coordinate axes and a rotation mechanism (not illustrated) that rotates the needle 19a around the central axis of the needle 19a.

The three-dimensional coordinate axes are independent of the triaxial rectangular coordinate system of the sample stage. The three-dimensional coordinate axes are a triaxial rectangular coordinate system with two-dimensional coordinate axes parallel to the surface of the stage 12. When the surface of the stage 12 is in a tilted or rotated state, this coordinate system will be tilted and rotated.

The computer 22 controls at least the stage drive mechanism 13, the focused ion beam-emitting optical system 14, the electron beam-emitting optical system 15, the gas supply unit 17, and the needle drive mechanism 19b.

The computer 22 is disposed outside the sample chamber 11. The computer 22 is connected to a display device 21 and input devices 23 such as a mouse and keyboard that output signals in response to input operations made by the operator. The computer 22 controls the overall operation of the charged particle beam device 10 according to signals output from the input devices 23 or signals generated by a predetermined automatic operation control process.

The computer 22 derives the beam diameter of the charged particle beam emitted by the focused ion beam-emitting optical system 14. An example of a beam diameter is expressed as in Equation 1.

$${D = [ {( 2 M + Rs )}^{2} + {\{ ( 1 / 2 ) \times Csi \times {ai}^{3} \}}^{2} + {( Cci \times ai \times Δ V / V )}^{2} )}^{0.5} \qquad ( 1 )$$

In Equation (1), D is the beam diameter, M is the optical system magnification, Rs is the source radius, Csi is the spherical aberration coefficient, ai is the image plane opening half angle, Cci is the chromatic aberration coefficient, AV is the energy spread, and V is the acceleration energy.

The computer 22 sets multiple irradiation locations for the charged particle beam D on the basis of the derived beam diameter D of the charged particle beam. An example of the multiple irradiation locations for the charged particle beam is the spacing between adjacent irradiation locations for the charged particle beam. The computer 22 sets the spacing between irradiation locations where the charged particle beams are adjacent to each other from a small value to a large value as the beam diameter of the charged particle beam increases from a small value to a large value. irradiation location

The computer 22 sets the number of scans on the basis of the multiple irradiation locations of the charged particle beam. Based on the information identifying the multiple irradiation locations of the charged particle beam and the number of scans, the computer 22 creates control signals to cause the focused ion beam-emitting optical system 14 and the stage drive mechanism 13 to emit the charged particle beam to each of the multiple irradiation locations.

The computer 22 outputs control signals to the focused ion beam-emitting optical system 14 and the stage drive mechanism 13. The focused ion beam-emitting optical system 14 acquires the control signal output from the computer 22 and controls inputs to a lens electrode and a scan electrode of the focused ion beam-emitting optical system 14 according to the acquired control signal, thereby controlling the irradiation location, beam diameter, and beam amount of the charged particle beam emitted by the focused ion beam-emitting optical system 14. The stage drive mechanism 13 acquires a control signal output from the computer 22, and controls the irradiation location of the charged particle beam emitted by the focused ion beam-emitting optical system 14 according to the acquired control signals by displacing the stage 12 with respect to a predetermined axis.

The computer 22 converts the detected amount of secondary charged particles R detected by the detector 16 while scanning the irradiation location of the charged particle beam into a brightness signal on the irradiation location, and generates image data showing the shape of the irradiation target on the basis of the two-dimensional positional distribution of the detected amount of secondary charged particles R. In an absorption current imaging mode, the computer 22 detects the absorption current flowing to the needle 19a while scanning the irradiation location of the charged particle beam, thereby generating absorption current image data that indicates the shape of the needle 19a in the form of the two-dimensional positional distribution of the absorbed current (absorption current image).

The computer 22 displays a screen on the display unit 21 for allowing operations such as zooming in, zooming out, moving, and rotating each image data, as well as each piece of the generated image data. The computer 22 displays a screen on display unit 21 for allowing various setting operations such as mode selection and processing settings in an automatic sequence control process.

A sample processing method using the charged particle beam device 10 with the configuration described above will be described below. One irradiation unit irradiated with a charged particle beam is called “one pixel”, and one irradiation region, which is a set of irradiation units, is called “one frame”. In the present embodiment, different pixels are irradiated for each scan by shifting the location of irradiation.

FIG. 2 is a diagram illustrating Example 1 of a location to be irradiated with a charged particle beam of the charged particle beam device according to the embodiment. In FIG. 2, “A” through “L” indicate pixels. In FIG. 2, (1) indicates a location (frame 1) to which the focused ion beam-emitting optical system 14 emits a charged particle beam during a first scan, (2) indicates a location (frame 2) to which the focused ion beam-emitting optical system 14 emits a charged particle beam during a second scan, and (3) indicates a location (frame 3) to which the focused ion beam-emitting optical system 14 emits a charged particle beam during a third scan.

The focused ion beam-emitting optical system 14 sequentially emits the charged particle beam to pixel A, pixel D, pixel G, and pixel J in this order during the first scan, to pixel B, pixel E, pixel H, and pixel K in this order during the second scan, and to pixel C, pixel F, pixel I, and pixel L in this order during the third scan while the gas supply unit 17 supplies etching gas such as compound gas.

Secondary electrons are generated when the focused ion beam-emitting optical system 14 irradiates pixel A with a charged particle beam. The generated secondary electrons decompose the compound gas adsorbed in pixel A, so that etching can be performed in pixel A. Since the generated secondary electrons spread over an area wider than the irradiation region of the charged particle beam, it is assumed that the compound gas in the vicinity of pixel A of the sample is decomposed by the charged particle beam irradiation so that a small amount of compound gas remains in the vicinity of pixel A. It is assumed that even though pixel B or pixel C in the vicinity of pixel A is irradiated with a charged particle beam after pixel A is irradiated with a charged particle beam, the etching processing will not be sufficiently performed in pixel B or C because there is a small amount of compound gas to be decomposed in pixel B or pixel C.

The focused ion beam-emitting optical system 14 irradiates pixel D with a charged particle beam after irradiating pixel A with a charged particle beam. Since pixel D is far from pixel A, it is assumed that a sufficient amount of compound gas remains in pixel D. Secondary electrons are generated when the focused ion beam-emitting optical system 14 irradiates pixel D with a charged particle beam. The generated secondary electrons decompose the compound gas adsorbed in pixel D, so that etching can be performed in pixel D. Since the generated secondary electrons spread over an area wider than the irradiation region of the charged particle beam, it is assumed that the compound gas in the vicinity of pixel D of the sample is decomposed by the charged particle beam irradiation so that a small amount of compound gas remains in the vicinity of pixel D. It is assumed that even though pixel E or pixel F in the vicinity of pixel D is irradiated with a charged particle beam after pixel D is irradiated with a charged particle beam, the etching processing will not be sufficiently performed in pixel E or pixel F because there remains a small amount of compound gas to be decomposed in pixel E or pixel F.

The focused ion beam-emitting optical system 14 irradiates pixel G with a charged particle beam after irradiating pixel D with a charged particle beam. Since pixel G is far from pixel D, it is assumed that a sufficient amount of compound gas remains in pixel G. Secondary electrons are generated when the focused ion beam-emitting optical system 14 irradiates pixel G with a charged particle beam. The generated secondary electrons decompose the compound gas adsorbed in pixel G, so that etching is performed in pixel G. Since the generated secondary electrons spread over an area wider than the irradiation region of the charged particle beam, it is assumed that the compound gas in the vicinity of pixel G of the sample is decomposed by the charged particle beam irradiation so that a small amount of compound gas remains in the vicinity of pixel G. It is assumed that even though pixel H or pixel I in the vicinity of pixel G is irradiated with a charged particle beam after pixel G is irradiated with a charged particle beam, the etching processing will not be sufficiently performed in pixel H or pixel I because there remains a small amount of compound gas to be decomposed in pixel H or pixel I.

The focused ion beam-emitting optical system 14 irradiates pixel J with a charged particle beam after irradiating pixel G with a charged particle beam. Since pixel J is far from pixel G, it is assumed that a sufficient amount of compound gas remains in pixel J. Secondary electrons are generated when the focused ion beam-emitting optical system 14 irradiates pixel J with a charged particle beam. The generated secondary electrons decompose the compound gas adsorbed in pixel J, so that etching is performed. In this way, a first scan is completed.

The focused ion beam-emitting optical system 14 irradiates pixel B with a charged particle beam after irradiating pixel J with a charged particle beam. In pixel B, the absorbed compound gas is partially decomposed when pixel A is irradiated by the charged particle beam and thus the remaining compound gas is reduced. However, since pixel B is replenished with the compound gas while pixel D, pixel G, and pixel J are irradiated with the charged particle beam, it is assumed that there is enough compound gas in pixel B. Secondary electrons are generated when the focused ion beam-emitting optical system 14 irradiates pixel B with a charged particle beam. The generated secondary electrons decompose the compound gas adsorbed in pixel B, so that etching is performed in pixel B. Since the generated secondary electrons spread over an area wider than the irradiation region of the charged particle beam, it is assumed that the compound gas in the vicinity of pixel B of the sample is decomposed by the charged particle beam irradiation so that a small amount of compound gas remains in the vicinity of pixel B. It is assumed that even though pixel C in the vicinity of pixel B is irradiated with a charged particle beam after pixel B is irradiated with a charged particle beam, the etching processing will not be sufficiently performed in pixel C because there is a small amount of compound gas to be decomposed in pixel C.

The focused ion beam-emitting optical system 14 irradiates pixel E with a charged particle beam after irradiating pixel B with a charged particle beam. Since pixel E is far from pixel B, it is assumed that a sufficient amount of compound gas remains in pixel E. Secondary electrons are generated when the focused ion beam-emitting optical system 14 irradiates pixel E with a charged particle beam. The generated secondary electrons decompose the compound gas adsorbed in pixel E, so that etching is performed in pixel E. Since the generated secondary electrons spread over an area wider than the irradiation region of the charged particle beam, it is assumed that the compound gas in the vicinity of pixel E of the sample is decomposed by the charged particle beam irradiation so that a small amount of compound gas remains in the vicinity of pixel E. It is assumed that even though pixel F in the vicinity of pixel E is irradiated with a charged particle beam after pixel E is irradiated with a charged particle beam, the etching processing will not be sufficiently performed in pixel F because there is a small amount of compound gas to be decomposed in pixel F.

The focused ion beam-emitting optical system 14 irradiates pixel H with a charged particle beam after irradiating pixel E with a charged particle beam. Since pixel H is far from pixel E, it is assumed that a sufficient amount of compound gas remains in pixel H. Secondary electrons are generated when the focused ion beam-emitting optical system 14 irradiates pixel H with a charged particle beam. The generated secondary electrons decompose the compound gas adsorbed in pixel H, so that etching is performed in pixel H. Since the generated secondary electrons spread over an area wider than the irradiation region of the charged particle beam, it is assumed that the compound gas in the vicinity of pixel H of the sample is decomposed by the charged particle beam irradiation so that a small amount of compound gas remains in the vicinity of pixel H. It is assumed that even though pixel I in the vicinity of pixel H is irradiated with a charged particle beam after pixel H is irradiated with a charged particle beam, the etching processing will not be sufficiently performed in pixel I because there is a small amount of compound gas to be decomposed in pixel I.

The focused ion beam-emitting optical system 14 irradiates pixel K with a charged particle beam after irradiating pixel H with a charged particle beam. Since pixel K is far from pixel H, it is assumed that a sufficient amount of compound gas remains in pixel K. Secondary electrons are generated when the focused ion beam-emitting optical system 14 irradiates pixel K with a charged particle beam. The generated secondary electrons decompose the compound gas adsorbed in pixel K, so that etching is performed in pixel K. In this way, a second scan is completed.

The focused ion beam-emitting optical system 14 irradiates pixel C with a charged particle beam after irradiating pixel K with a charged particle beam. In pixel C, the absorbed compound gas is decomposed when pixel B is irradiated with the charged particle beam and thus the remaining compound gas is reduced. However, since pixel C is replenished with the compound gas while pixel E, pixel H, and pixel K are irradiated with the charged particle beam, it is assumed that there is enough compound gas in pixel C. Secondary electrons are generated when the focused ion beam-emitting optical system 14 irradiates pixel C with a charged particle beam. The generated secondary electrons decompose the compound gas adsorbed in pixel C, so that etching is performed in pixel C. Since the generated secondary electrons spread over an area wider than the irradiation region of the charged particle beam, it is assumed that the compound gas in the vicinity of pixel C of the sample is decomposed by the charged particle beam irradiation so that a small amount of compound gas remains in the vicinity of pixel C.

The focused ion beam-emitting optical system 14 irradiates pixel F with a charged particle beam after irradiating pixel C with a charged particle beam. Since pixel F is far from pixel C, it is assumed that a sufficient amount of compound gas remains in pixel F. Secondary electrons are generated when the focused ion beam-emitting optical system 14 irradiates pixel F with a charged particle beam. The generated secondary electrons decompose the compound gas adsorbed in pixel F, so that etching is performed in pixel F. Since the generated secondary electrons spread over an area wider than the irradiation region of the charged particle beam, it is assumed that the compound gas in the vicinity of pixel F of the sample is decomposed by the charged particle beam irradiation so that a small amount of compound gas remains in the vicinity of pixel F.

The focused ion beam-emitting optical system 14 irradiates pixel I with a charged particle beam after irradiating pixel F with a charged particle beam. Since pixel I is far from pixel F, it is assumed that a sufficient amount of compound gas remains in pixel I. Secondary electrons are generated when the focused ion beam-emitting optical system 14 irradiates pixel I with a charged particle beam. The generated secondary electrons decompose the compound gas adsorbed in pixel I, so that etching is performed in pixel I. Since the generated secondary electrons spread over an area wider than the irradiation region of the charged particle beam, it is assumed that the compound gas in the vicinity of pixel I of the sample is decomposed by the charged particle beam irradiation so that a small amount of compound gas remains in the vicinity of pixel I.

The focused ion beam-emitting optical system 14 irradiates pixel L with a charged particle beam after irradiating pixel I with a charged particle beam. Since pixel L is far from pixel I, it is assumed that a sufficient amount of compound gas remains in pixel L. Secondary electrons are generated when the focused ion beam-emitting optical system 14 irradiates pixel L with a charged particle beam. The generated secondary electrons decompose the compound gas adsorbed in pixel L, so that etching is performed in pixel L. In this way, a third scan is completed.

In this way, the charged particle beam device 10 sets different pixels on the sample V for each scan and emits a charged particle beam to the set pixels. In the example illustrated in FIG. 2, a case in which the spacing between the pixels to be irradiated with a charged particle beam is 2 pixels for each scan, but embodiments are not limited to this case. For example, for each scan, the spacing between the pixels irradiated with the charged particle beam may be one pixel, or three or more pixels. In the example illustrated in FIG. 2, the number of scans (number of irradiation processes) is 3 but it is not limited to the number. For example, the number of scans may be two, or the number of scans may be four or more. The number of pixels irradiated with the charged particle beam can be set to any number according to the beam diameter.

Next, the processing procedure of the charged particle beam device 10 will be described. FIG. 3 is a flowchart illustrating processing procedures of the charged particle beam device according to the present embodiment. The charged particle beam device 10 performs the processes described below while the gas supply unit 17 supplies an etching gas, such as a compound gas.

(Step S1) In the charged particle beam device 10, the computer 22 derives a plurality of irradiation locations of the charged particle beam D based on the derived beam diameter D of the charged particle beam, and sets the derived plurality of irradiation locations.

(Step S2) In the charged particle beam device 10, the computer 22 sets multiple irradiation locations for a charged particle beam D on the basis of the derived beam diameter D of the charged particle beam.

(Step S3) In the charged particle beam system 10, the computer 22 derives the number of scans on the basis of the set multiple irradiation locations of the set charged particle beam D and sets the derived number of scans.

(Step S4) In the charged particle beam device 10, the computer 22 creates control signals to cause the focused ion beam-emitting optical system 14 and the stage drive mechanism 13 to emit the charged particle beam to each of the multiple irradiation locations on the basis of the information specifying the multiple irradiation locations and the information specifying the number of scans.

(Step S5) In the charged particle beam device 10, the computer 22 outputs control signals to the focused ion beam-emitting optical system 14 and the stage drive mechanism 13. The focused ion beam-emitting optical system 14 and the stage drive mechanism 13 acquire the control signals from the computer 22 and perform scanning on the basis of the acquired control signals.

In the aforementioned embodiment, the case in which the charged particle beam device 10 derives a plurality of irradiation locations of the charged particle beam D on the basis of the beam diameter of the charged particle beam to be emitted by the focused ion beam-emitting optical system 14 is described, but embodiments are not limited to the described embodiment. For example, the computer 22 may derive multiple irradiation locations of the charged particle beam D on the basis of an acceleration voltage. The profile of the charged particle beam changes according to the acceleration voltage. The computer 22 may shorten the spacing between irradiation locations as the sharpness of the profile (shape) of the charged particle beam deice is increased. The computer 22 may also derive multiple irradiation locations of the charged particle beam D on the basis of the current density distribution of the charged particle beam. The computer 22 sets the spacing between irradiation locations where the charged particle beams are adjacent to each other from a small value to a large value as the current density distribution of the charged particle beam increases from a small value to a large value. In addition, the computer sets a location to be irradiated with a charged particle beam as the processing region based on whether a charged particle emitted from the charged particle beam-emitting optical system is an electron, ion, or ionic species.

In the aforementioned embodiment, the case in which the charged particle beam device 10 irradiates the sample with a charged particle beam in one direction is described, but embodiments are not limited to the case. For example, the charged particle beam device 10 may be designed to irradiate different pixels in each scan by shifting the irradiation location in two directions. The charged-particle beam device 10 irradiates different pixels in each scan by shifting the location to be irradiated in two directions, i.e., the X-axis direction and the Y-axis direction.

FIG. 4 is a diagram illustrating Example 2 of a location to be irradiated with a charged particle beam of the charged particle beam device according to the embodiment. In FIG. 4, “A” through “L” indicate pixels. In FIG. 4, (1) indicates a location (frame 1) to which the focused ion beam-emitting optical system 14 emits a charged particle beam during a first scan, and (2) indicates a location (frame 2) to which the focused ion beam-emitting optical system 14 emits a charged particle beam during a second scan.

In the example illustrated in the figure, during the first scan, the focused ion beam-emitting optical system 14 sequentially emits a charged particle beam to 72 locations: pixel A, pixel C, pixel E, pixel G, pixel I, and pixel K in the first line; pixel B, pixel D, pixel F, pixel H, pixel J, and pixel L in the second line; . . . , . . . , pixel B, pixel D, pixel F, pixel H, pixel J, and pixel L in the twelfth line. During the second scan, the focused beam-emitting optical system 14 sequentially emits a charged particle beam to 72 locations: pixel B, pixel D, pixel F, pixel H, pixel J, and pixel L in the first line, pixel A, pixel C, pixel E, pixel G, pixel I, and pixel K in the second line, . . . , pixel A, pixel C, pixel E, pixel G, pixel I, and pixel K in the twelfth line.

The processing of the first scan for the first line is described below. The focused ion beam-emitting optical system 14 of the charged particle beam devices 10 emits a charged particle beam to pixel A while the gas supply unit 17 supplies etching gas. The generated secondary electrons generated due to the charged particle beam emitted from the focused ion beam-emitting optical system 14 decompose a compound gas adsorbed in pixel A, so that etching is performed in pixel A. Since the generated secondary electrons spread over an area wider than the irradiation region of the charged particle beam, it is assumed that the compound gas in the vicinity of pixel A of the sample is decomposed by the charged particle beam irradiation so that a small amount of compound gas remains in the vicinity of pixel A.

The focused ion beam-emitting optical system 14 irradiates pixel C with a charged particle beam after irradiating pixel A with a charged particle beam. Since pixel C is far from pixel A, it is assumed that a sufficient amount of compound gas remains in pixel C. The generated secondary electrons generated due to the irradiation of the charged particle beam emitted from the focused ion beam-emitting optical system 14 decompose a compound gas adsorbed in pixel C, so that etching is performed in pixel C. Since the generated secondary electrons spread over an area wider than the irradiation region of the charged particle beam, it is assumed that the compound gas in the vicinity of pixel C of the sample is decomposed by the charged particle beam irradiation so that a small amount of compound gas remains in the vicinity of pixel C.

The focused ion beam-emitting optical system 14 irradiates pixel E with a charged particle beam after irradiating pixel C with a charged particle beam. Since pixel E is far from pixel C, it is assumed that a sufficient amount of compound gas remains in pixel E. The generated secondary electrons generated due to the irradiation of the charged particle beam emitted from the focused ion beam-emitting optical system 14 decompose a compound gas adsorbed in pixel E, so that etching is performed in pixel E. Since the generated secondary electrons spread over an area wider than the irradiation region of the charged particle beam, it is assumed that the compound gas in the vicinity of pixel E of the sample is decomposed by the charged particle beam irradiation so that a small amount of compound gas remains in the vicinity of pixel E.

The focused ion beam-emitting optical system 14 irradiates pixel G with a charged particle beam after irradiating pixel E with a charged particle beam. Since pixel G is far from pixel E, it is assumed that a sufficient amount of compound gas remains in pixel G. The generated secondary electrons generated due to the irradiation of the charged particle beam emitted from the focused ion beam-emitting optical system 14 decompose a compound gas adsorbed in pixel G, so that etching is performed in pixel G. Since the generated secondary electrons spread over an area wider than the irradiation region of the charged particle beam, it is assumed that the compound gas in the vicinity of pixel G of the sample is decomposed by the charged particle beam irradiation so that a small amount of compound gas remains in the vicinity of pixel G.

The focused ion beam-emitting optical system 14 irradiates pixel I with a charged particle beam after irradiating pixel G with a charged particle beam. Since pixel I is far from pixel G, it is assumed that a sufficient amount of compound gas remains in pixel I. The generated secondary electrons generated due to the irradiation of the charged particle beam emitted from the focused ion beam-emitting optical system 14 decompose a compound gas adsorbed in pixel I, so that etching is performed in pixel I. Since the generated secondary electrons spread over an area wider than the irradiation region of the charged particle beam, it is assumed that the compound gas in the vicinity of pixel I of the sample is decomposed by the charged particle beam irradiation so that a small amount of compound gas remains in the vicinity of pixel I.

The focused ion beam-emitting optical system 14 irradiates pixel K with a charged particle beam after irradiating pixel I with a charged particle beam. Since pixel K is far from pixel I, it is assumed that a sufficient amount of compound gas remains in pixel K. The generated secondary electrons generated due to the irradiation of the charged particle beam emitted from the focused ion beam-emitting optical system 14 decompose a compound gas adsorbed in pixel K, so that etching is performed in pixel K. In this way the scan for the first line is completed.

The processing of the first scan for the second line is described below. The focused ion beam-emitting optical system 14 irradiates pixel B with a charged particle beam after irradiating pixel K in the first line with a charged particle beam. In pixel B, the absorbed compound gas is decomposed when pixel A in the first line is irradiated with the charged particle beam and thus the remaining compound gas is reduced. However, since pixel B is replenished with the compound gas while pixel C, pixel E, pixel G, pixel I, and pixel K in the first line are irradiated with a charged particle beam, it is assumed that the amount of the compound gas in pixel B becomes sufficient. Since the generated secondary electrons generated when the focused ion beam-emitting optical system 14 emits a charged particle beam to pixel B decompose a compound gas adsorbed in pixel B, etching occurs in pixel B. Since the generated secondary electrons spread over an area wider than the irradiation region of the charged particle beam, it is assumed that the compound gas in the vicinity of pixel B of the sample is decomposed by the charged particle beam irradiation so that a small amount of compound gas remains in the vicinity of pixel B.

The focused ion beam-emitting optical system 14 irradiates pixel D with a charged particle beam after irradiating pixel B with a charged particle beam. Since pixel D is far from pixel B, it is assumed that a sufficient amount of compound gas remains in pixel D. The generated secondary electrons generated due to the irradiation of the charged particle beam emitted from the focused ion beam-emitting optical system 14 decompose a compound gas adsorbed in pixel D, so that etching can be performed in pixel D. Since the generated secondary electrons spread over an area wider than the irradiation region of the charged particle beam, it is assumed that the compound gas in the vicinity of pixel D of the sample is decomposed by the charged particle beam irradiation so that a small amount of compound gas remains in the vicinity of pixel D.

The focused ion beam-emitting optical system 14 irradiates pixel F with a charged particle beam after irradiating pixel D with a charged particle beam. Since pixel F is far from pixel D, it is assumed that a sufficient amount of compound gas remains in pixel F. The generated secondary electrons generated due to the irradiation of the charged particle beam emitted from the focused ion beam-emitting optical system 14 decompose a compound gas adsorbed in pixel F, so that etching can be performed in pixel F. Since the generated secondary electrons spread over an area wider than the irradiation region of the charged particle beam, it is assumed that the compound gas in the vicinity of pixel F of the sample is decomposed by the charged particle beam irradiation so that a small amount of compound gas remains in the vicinity of pixel F.

The focused ion beam-emitting optical system 14 irradiates pixel H with a charged particle beam after irradiating pixel F with a charged particle beam. Since pixel H is far from pixel F, it is assumed that a sufficient amount of compound gas remains in pixel H. The generated secondary electrons generated due to the irradiation of the charged particle beam emitted from the focused ion beam-emitting optical system 14 decompose a compound gas adsorbed in pixel H, so that etching can be performed in pixel H. Since the generated secondary electrons spread over an area wider than the irradiation region of the charged particle beam, it is assumed that the compound gas in the vicinity of pixel H of the sample is decomposed by the charged particle beam irradiation so that a small amount of compound gas remains in the vicinity of pixel H.

The focused ion beam-emitting optical system 14 irradiates pixel J with a charged particle beam after irradiating pixel H with a charged particle beam. Since pixel J is far from pixel H, it is assumed that a sufficient amount of compound gas remains in pixel J. The generated secondary electrons generated due to the irradiation of the charged particle beam emitted from the focused ion beam-emitting optical system 14 decompose a compound gas adsorbed in pixel J, so that etching can be performed in pixel J. Since the generated secondary electrons spread over an area wider than the irradiation region of the charged particle beam, it is assumed that the compound gas in the vicinity of pixel J of the sample is decomposed by the charged particle beam irradiation so that a small amount of compound gas remains in the vicinity of pixel J.

The focused ion beam-emitting optical system 14 irradiates pixel L with a charged particle beam after irradiating pixel J with a charged particle beam. Since pixel L is far from pixel J, it is assumed that a sufficient amount of compound gas remains in pixel L. The generated secondary electrons generated due to the irradiation of the charged particle beam emitted from the focused ion beam-emitting optical system 14 decompose a compound gas adsorbed in pixel L, so that etching can be performed in pixel L. In this way the scan for the second line is completed. To the third line through the twelfth line, the process for the first line to the second line can be applied. Therefore, a redundant description for the etching processing for the third line through the twelfth line is omitted. In this way, the first scan is completed.

The processing of the second scan for the first line is described below. The focused ion beam-emitting optical system 14 of the charged particle beam devices 10 emits a charged particle beam to pixel B while the gas supply unit 17 supplies etching gas. The generated secondary electrons generated due to the irradiation of the charged particle beam emitted from the focused ion beam-emitting optical system 14 decompose a compound gas adsorbed in pixel B, so that etching can be performed in pixel B. Since the generated secondary electrons spread over an area wider than the irradiation region of the charged particle beam, it is assumed that the compound gas in the vicinity of pixel B of the sample is decomposed by the charged particle beam irradiation so that a small amount of compound gas remains in the vicinity of pixel B.

The focused ion beam-emitting optical system 14 irradiates pixel D with a charged particle beam after irradiating pixel B with a charged particle beam. Since pixel D is far from pixel B, it is assumed that a sufficient amount of compound gas remains in pixel D. The generated secondary electrons generated due to the irradiation of the charged particle beam emitted from the focused ion beam-emitting optical system 14 decompose a compound gas adsorbed in pixel D, so that etching can be performed in pixel D. Since the generated secondary electrons spread over an area wider than the irradiation region of the charged particle beam, it is assumed that the compound gas in the vicinity of pixel D of the sample is decomposed by the charged particle beam irradiation so that a small amount of compound gas remains in the vicinity of pixel D.

The focused ion beam-emitting optical system 14 irradiates pixel F with a charged particle beam after irradiating pixel D with a charged particle beam. Since pixel F is far from pixel D, it is assumed that a sufficient amount of compound gas remains in pixel F. The generated secondary electrons generated due to the irradiation of the charged particle beam emitted from the focused ion beam-emitting optical system 14 decompose a compound gas adsorbed in pixel F, so that etching can be performed in pixel F. Since the generated secondary electrons spread over an area wider than the irradiation region of the charged particle beam, it is assumed that the compound gas in the vicinity of pixel F of the sample is decomposed by the charged particle beam irradiation so that a small amount of compound gas remains in the vicinity of pixel F.

The focused ion beam-emitting optical system 14 irradiates pixel H with a charged particle beam after irradiating pixel F with a charged particle beam. Since pixel H is far from pixel F, it is assumed that a sufficient amount of compound gas remains in pixel H. The generated secondary electrons generated due to the irradiation of the charged particle beam emitted from the focused ion beam-emitting optical system 14 decompose a compound gas adsorbed in pixel H, so that etching can be performed in pixel H. Since the generated secondary electrons spread over an area wider than the irradiation region of the charged particle beam, it is assumed that the compound gas in the vicinity of pixel HI of the sample is decomposed by the charged particle beam irradiation so that a small amount of compound gas remains in the vicinity of pixel H.

The focused ion beam-emitting optical system 14 irradiates pixel J with a charged particle beam after irradiating pixel H with a charged particle beam. Since pixel J is far from pixel H, it is assumed that a sufficient amount of compound gas remains in pixel J. The generated secondary electrons generated due to the irradiation of the charged particle beam emitted from the focused ion beam-emitting optical system 14 decompose a compound gas adsorbed in pixel J, so that etching can be performed in pixel J. Since the generated secondary electrons spread over an area wider than the irradiation region of the charged particle beam, it is assumed that the compound gas in the vicinity of pixel J of the sample is decomposed by the charged particle beam irradiation so that a small amount of compound gas remains in the vicinity of pixel J.

The focused ion beam-emitting optical system 14 irradiates pixel L with a charged particle beam after irradiating pixel J with a charged particle beam. Since pixel L is far from pixel J, it is assumed that a sufficient amount of compound gas remains in pixel L. The generated secondary electrons generated due to the irradiation of the charged particle beam emitted from the focused ion beam-emitting optical system 14 decompose a compound gas adsorbed in pixel L, so that etching can be performed in pixel L. In this way the scan for the first line is completed.

The processing of the second scan for the second line is described below. The focused ion beam-emitting optical system 14 irradiates pixel A with a charged particle beam after irradiating pixel L in the first line with a charged particle beam. In pixel A, the absorbed compound gas is decomposed when pixel B in the first line is irradiated with the charged particle beam and thus the remaining compound gas is reduced. However, since pixel A is replenished with the compound gas while pixel D, pixel F, pixel H, pixel J, and pixel L in the first line are irradiated with a charged particle beam, it is assumed that the amount of the compound gas in pixel A becomes sufficient. Since the generated secondary electrons generated when the focused ion beam-emitting optical system 14 emits a charged particle beam to pixel B decompose a compound gas adsorbed in pixel A, etching occurs in pixel A. Since the generated secondary electrons spread over an area wider than the irradiation region of the charged particle beam, it is assumed that the compound gas in the vicinity of pixel A of the sample is decomposed by the charged particle beam irradiation so that a small amount of compound gas remains in the vicinity of pixel A.

The focused ion beam-emitting optical system 14 irradiates pixel C with a charged particle beam after irradiating pixel A with a charged particle beam. Since pixel C is far from pixel A, it is assumed that a sufficient amount of compound gas remains in pixel C. The generated secondary electrons generated due to the irradiation of the charged particle beam emitted from the focused ion beam-emitting optical system 14 decompose a compound gas adsorbed in pixel C, so that etching can be performed in pixel C. Since the generated secondary electrons spread over an area wider than the irradiation region of the charged particle beam, it is assumed that the compound gas in the vicinity of pixel C of the sample is decomposed by the charged particle beam irradiation so that a small amount of compound gas remains in the vicinity of pixel C.

The focused ion beam-emitting optical system 14 irradiates pixel E with a charged particle beam after irradiating pixel C with a charged particle beam. Since pixel E is far from pixel C, it is assumed that a sufficient amount of compound gas remains in pixel E. The generated secondary electrons generated due to the irradiation of the charged particle beam emitted from the focused ion beam-emitting optical system 14 decompose a compound gas adsorbed in pixel E, so that etching is performed in pixel E. Since the generated secondary electrons spread over an area wider than the irradiation region of the charged particle beam, it is assumed that the compound gas in the vicinity of pixel E of the sample is decomposed by the charged particle beam irradiation so that a small amount of compound gas remains in the vicinity of pixel E.

The focused ion beam-emitting optical system 14 irradiates pixel G with a charged particle beam after irradiating pixel E with a charged particle beam. Since pixel G is far from pixel E, it is assumed that a sufficient amount of compound gas remains in pixel G. The generated secondary electrons generated due to the irradiation of the charged particle beam emitted from the focused ion beam-emitting optical system 14 decompose a compound gas adsorbed in pixel G, so that etching is performed in pixel G. Since the generated secondary electrons spread over an area wider than the irradiation region of the charged particle beam, it is assumed that the compound gas in the vicinity of pixel G of the sample is decomposed by the charged particle beam irradiation so that a small amount of compound gas remains in the vicinity of pixel G.

The focused ion beam-emitting optical system 14 irradiates pixel I with a charged particle beam after irradiating pixel G with a charged particle beam. Since pixel I is far from pixel G, it is assumed that a sufficient amount of compound gas remains in pixel I. The generated secondary electrons generated due to the irradiation of the charged particle beam emitted from the focused ion beam-emitting optical system 14 decompose a compound gas adsorbed in pixel I, so that etching is performed in pixel I. Since the generated secondary electrons spread over an area wider than the irradiation region of the charged particle beam, it is assumed that the compound gas in the vicinity of pixel I of the sample is decomposed by the charged particle beam irradiation so that a small amount of compound gas remains in the vicinity of pixel I.

The focused ion beam-emitting optical system 14 irradiates pixel K with a charged particle beam after irradiating pixel I with a charged particle beam. Since pixel K is far from pixel I, it is assumed that a sufficient amount of compound gas remains in pixel K. The generated secondary electrons generated due to the irradiation of the charged particle beam emitted from the focused ion beam-emitting optical system 14 decompose a compound gas adsorbed in pixel K, so that etching is performed in pixel K. In this way the scan for the second line is completed. To the third line through the twelfth line, the process for the first line to the second line can be applied. Therefore, a redundant description for the etching processing for the third line through the twelfth line is omitted. In this way, the second scan is completed.

In addition, for example, when the charged particle beam device 10 emits a charged particle beam while scanning in two directions, the X-axis and the Y-axis, the device may emit the charged particle beam to pixels that are not consecutively arranged, i.e. pixels that are arranged with a spacing of at least one or more lines for each scan.

FIG. 5 is a diagram illustrating Example 3 of a location to be irradiated with a charged particle beam of the charged particle beam device according to the embodiment. In FIG. 5, (1) indicates a location (frame 1) to which the focused ion beam-emitting optical system 14 emits a charged particle beam during a first scan, (2) indicates a location (frame 2) to which the focused ion beam-emitting optical system 14 emits a charged particle beam during a second scan, (3) indicates a location (frame 3) to which the focused ion beam-emitting optical system 14 emits a charged particle beam during a third scan, and (4) indicates a location (frame 4) to which the focused ion beam-emitting optical system 14 emits a charged particle beam during a fourth scan.

The charged particle beam device 10 emits a charged particle beam to different pixels of the sample V for each scan. In the example illustrated in FIG. 5, a case in which the spacing between the pixels to be irradiated with a charged particle beam is 1 pixel for each scan in two directions, i.e., X- and Y-axes, but embodiments are not limited to this case. For example, for each scan, the spacing between the pixels irradiated with the charged particle beams may be two or more pixels. For example, the spacing between the pixels irradiated with the charged particle beams in the X-axis direction may be different from that in the Y-axis direction. In the example illustrated in FIG. 5, the number of scans (number of irradiation processes) is 4 but the number of scans is not limited to 4. For example, the number of scans may be two or three, or the number of scans may be five or more. In FIG. 5, the scans indicated by (1) through (4) may be performed in any order.

This charged particle beam device 10 according to the present embodiment is a charged particle beam device that performs deposition processing or etching processing on a sample, and the charged particle beam device includes: a charged particle beam-emitting optical system as a focused ion beam-emitting optical system 14 that emits a charged particle beam; a sample stage that holds a sample; a drive mechanism as stage drive mechanism 13 that drives the sample stage; a gas supply unit that supplies an etching gas to the surface of the sample; and a computer 22 that sets a processing region of the sample and controls the charged particle beam-emitting optical system and the drive mechanism so as to irradiate the set processing region with a charged particle beam and etch the sample. The computer sets a different processing region for each scan on the sample. This configuration allows the etching gas to be supplied to the processing region between scans is performed, thereby reducing the time required for deposition processing compared to a process in which it is required to wait for the supply of the etching gas to the processing region for a single scan, and improving the effects of a gas-assisted etching process.

In addition, the computer 22 sets the irradiation location of the charged particle beam as a processing region according to the diameter or current density distribution of the charged particle beam emitted by the charged particle beam-emitting optical system. This configuration allows the irradiation location of the charged particle beam to be set such that the processing regions do not overlap based on the diameter or current density distribution of the charged particle beam.

In addition, the computer 22 sets the irradiation location of the charged particle beam as a processing region based on the acceleration voltage applied to the charged particles by the charged particle beam-emitting optical system. This configuration allows the irradiation location of the charged particle beam to be set such that the processing regions do not overlap based on the shape of the charged particle beam derived from the acceleration voltage.

In addition, the computer sets a location to be irradiated with the charged particle beam as the processing region based on whether charged particles emitted from the charged particle beam-emitting optical system are an electron, ion, or ionic species. With this configuration, the irradiation location of the charged particle beam can be set such that the processing areas do not overlap, according to whether the charged particle beam is an electron beam, an ion beam, or an ionic species beam.

The computer 22 sets a plurality of first irradiation locations spaced at predetermined intervals on the sample as the processing regions for deposition processing or etching processing, and sets one or more second irradiation locations between the first irradiation locations that are adjacent. This configuration allows the irradiation location of the charged particle beam to be set such that the processing regions do not overlap.

The computer 22 sets different processing regions for each scan in two orthogonal directions on the sample as the processing regions for deposition processing or etching processing. This configuration allows the irradiation location of the charged particle beam to be set such that the processing regions do not overlap in two directions orthogonal to each other.

A program to implement all or part of the control function of the computer 22 of the charged particle beam device may be recorded on a computer-readable recording medium, and the program recorded on the recording medium may be read and executed by a computer system. The term “computer system” here refers to a computer system built into a charged particle beam device D1 or a composite charged particle beam device D and provided with an operating system (OS) and hardware devices such as peripheral devices. Here, the term “computer-readable recording medium” refers to a portable medium such as flexible disk, optical magnetic disk, ROM, CD-ROM, and other storage device such as a hard disk built into the computer system. In addition, the term “computer-readable recording medium” may also include a medium that can dynamically hold the program for a short period of time, such as a communication line in the case where the program is transmitted over a network such as the Internet or a communication line such as a telephone line, and a medium that holds the program for a certain period of time, such as a volatile memory provided in a computer system serving as a server or a client. The program may be used to implement some of the aforementioned functions, and may also be used to implement the aforementioned functions in conjunction with a program recorded in the computer system.

In addition, in the embodiments described above, the computer 22 may be partially or fully implemented as an integrated circuit such as a large scale integrated (LSI) circuit. Each function of the computer 22 may be individually processorized, or it may be partially or fully integrated and processorized. The integrated circuit is not limited to LSI, but may be implemented as a dedicated circuit or general-purpose processor. When an integrated circuit technology has emerged as an alternative to LSI due to advances in semiconductor technology, an integrated circuit based on such technology may be used.

The embodiments of the invention have been described in detail with reference to the drawings, but the specific configuration of the invention is not limited to the embodiments and can include designs that do not depart from the gist of the invention.

### EXPLANATION OF REFERENCE SYMBOLS

10 . . . Charged particle beam device, 11 . . . Sample chamber, 12 . . . Stage (sample stage), 13 . . . Stage drive mechanism, 14 . . . Focused ion beam-emitting optical system (charged particle beam-emitting optical system), 15 . . . Electron beam-emitting optical system (charged particle beam-emitting optical system), 16 . . . Detector, 17 . . . Gas supply unit, 18 . . . Needle (sample piece transfer means), 18 . . . Gaseous ion beam-emitting optical system (charged particle beam-emitting optical system), 19a . . . Needle, 19b . . . Needle drive mechanism, 20 . . . Absorption current detector, 21 . . . Display device, 22 . . . Computer, 23 . . . Input device, 33 . . . Sample stand, 34 . . . Columnar portion, C . . . Inclined portion, P . . . Sample piece holder, Q . . . Micro sample piece, R . . . Secondary charged particle, S . . . Sample piece, V . . . Sample

1. A charged particle beam device performing deposition processing or etching processing on a sample, the charged particle beam device comprising:
a charged particle beam-emitting optical system that emits a charged particle beam;
a sample stage that holds a sample;
a drive mechanism that drives the sample stage;
a gas supply unit that supplies etching gas to a surface of the sample; and
a computer that sets a processing region of the sample and controls the charged particle beam-emitting optical system and the drive mechanism so that the processing region that is set is irradiated with a charged particle beam to perform etching processing of the sample,
wherein the computer sets a different processing region for each scan for the sample.

2. The charged particle beam device according to claim 1, wherein the computer sets a location to be irradiated with a charged particle beam as the processing region based on a diameter or current density distribution of the charged particle beam emitted by the charged particle beam-emitting optical system.

3. The charged particle beam device according to claim 2, wherein the computer sets a location to be irradiated with a charged particle beam as the processing region based on acceleration voltage which the charged particle beam-emitting optical system applies to charged particles.

4. The charged particle beam device according to claim 1, wherein the computer sets a location to be irradiated with a charged particle beam as the processing region based on whether a charged particle of the charged particle beam-emitting optical system is an electron, ion, or ionic species.

5. The charged particle beam device according to claim 1, wherein the computer sets a plurality of first irradiation locations spaced at a predetermined interval on the sample as the processing regions for performing deposition processing or etching processing and sets one or more second irradiation locations between the first irradiation locations that are adjacent.

6. The charged particle beam device according to claim 1, wherein the computer sets a different processing region for each scan in two orthogonal directions on the sample as the processing region for deposition processing or etching processing.

7. A method of controlling a charged particle beam device that performs deposition processing or etching processing on a sample and comprises a charged particle beam-emitting optical system that irradiates a charged particle beam, a sample stage that holds a sample, a drive mechanism that drives the sample stage, a gas supply unit that supplies etching gas to a surface of the sample, and a computer that sets a processing region of the sample, the method comprising:
setting a different processing region for each scan for the sample with the computer; and
controlling the charged particle beam-emitting optical system and the drive mechanism with the computer so as to irradiate the processing region with a charged particle beam to perform etching processing of the sample.

8. The charged particle beam device according to claim 3, wherein the computer sets a location to be irradiated with a charged particle beam as the processing region based on whether a charged particle of the charged particle beam-emitting optical system is an electron, ion, or ionic species.
